(19) United States
(12) Patent Application Publication
(10) Pub. No.: US 2024/0405131 A1
(43) Pub. Date: Dec. 5, 2024

(54) GUARD RING STRUCTURE AND COMPONENT STRUCTURE

(71) Applicant: LiVe Optronics Company Limited, Taipei City (TW)

(72) Inventors: CHAO-HSIN WU, Taipei City (TW); CHI-EN CHEN, Taipei City (TW); Natchanon Prechatavanich, Taipei City (TW)

(21) Appl. No.: 18/230,666

(22) Filed: Aug. 7, 2023

(30) Foreign Application Priority Data
Jun. 5, 2023 (TW) 112120795

(51) Int. Cl. H01L 31/0216; H01L 31/0236; H01L 31/107

(52) U.S. Cl. CPC H01L 31/02161; H01L 31/0236; H01L 31/107

(57) ABSTRACT

A guard ring structure and a component structure are provided. The guard ring structure includes a first attached guard ring and a second attached guard ring. The first attached guard ring is disposed at a periphery of an active region. The second attached guard ring is disposed at a periphery of the first attached guard ring. The first attached guard ring and the second attached guard ring are each an attached guard ring, and form a stepped structure. The guard ring structure is a stepped diffusion structure for an avalanche photodiode.

### CROSS-REFERENCE TO RELATED PATENT APPLICATION

This application claims the benefit of priority to Taiwan Patent Application No. 112120795, filed on Jun. 5, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a guard ring structure and a component structure, and more particularly to a guard ring structure and a component structure that are simplified.

### BACKGROUND OF THE DISCLOSURE

In a conventional process where indium gallium arsenide (InGaAs) is grown on indium phosphide (InP), edge breakdown occurs at a Zn diffusion edge of, for example, a planar avalanche photodiode due to a high electric field concentration effect. This may cause an increase of a dark count rate (DCR), a decrease of breakdown gain, and deterioration in jitter. Therefore, guard rings are used in the planar avalanche photodiode for dispersion of a fringe field, so as to prevent the edge breakdown. However, the guard rings have various types, each of which is different in terms of manufacturing difficulty and effect. The guard rings can also be classified as an attached guard ring (AGR) or a floating guard ring (FGR). If only the attached guard ring is independently used, dispersion of an electric field cannot be properly achieved.

### SUMMARY OF THE DISCLOSURE

In response to the above-referenced technical inadequacies, the present disclosure provides a guard ring structure and a component structure.

In order to solve the above-mentioned problems, one of the technical aspects adopted by the present disclosure is to provide a guard ring structure, which is applicable to an active region. The guard ring structure includes: a first attached guard ring disposed at a periphery of the active region; and a second attached guard ring disposed at a periphery of the first attached guard ring. The first attached guard ring and the second attached guard ring are each an attached guard ring (AGR), and form a stepped structure.

In order to solve the above-mentioned problems, another one of the technical aspects adopted by the present disclosure is to provide a component structure, which includes: an active region; and a guard ring structure disposed at a periphery of the active region. The guard ring structure includes a plurality of attached guard rings, and the attached guard rings jointly form a stepped structure.

Therefore, in the guard ring structure and the component structure provided by the present disclosure, the attached guard rings that form two or more steps and have the same structure are used for suppression of edge breakdown and for concentration of an electric field in the active region, so as to effectively improve detection efficiency and jitter. Furthermore, the guard ring structure of the present disclosure can be used in the component structure of various light detection and ranging (LIDAR) devices and avalanche photodiodes. Instead of using a floating guard ring, the attached guard ring is divided into two, or the single attached guard ring is divided into more than two attached guard rings that are disposed adjacent to one another. In this way, an area utilization rate can be effectively decreased, thereby lowering manufacturing costs and improving component characteristics.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a guard ring structure according to a first embodiment of the present disclosure;

FIG. 2 is a schematic enlarged view of region II of FIG. 1;

FIG. 3 is another schematic view of the guard ring structure according to the first embodiment of the present disclosure;

FIG. 4 is a schematic enlarged view of region IV of FIG. 3;

FIG. 5A is an electric field distribution diagram of a single attached guard ring;

FIG. 5B is an electric field distribution diagram of the guard ring structure of FIG. 1;

FIG. 5C is an electric field distribution diagram of the guard ring structure of FIG. 3;

FIG. 6 is a schematic view of a component structure according to a second embodiment of the present disclosure; and

FIG. 7 is another schematic view of the component structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

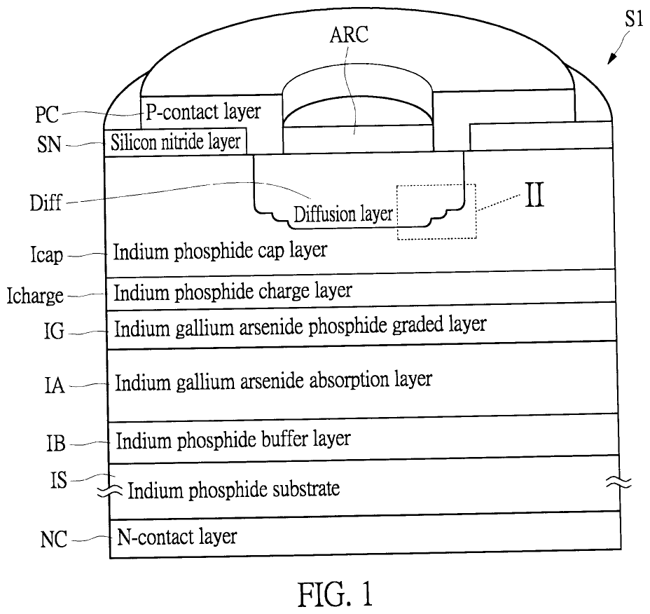

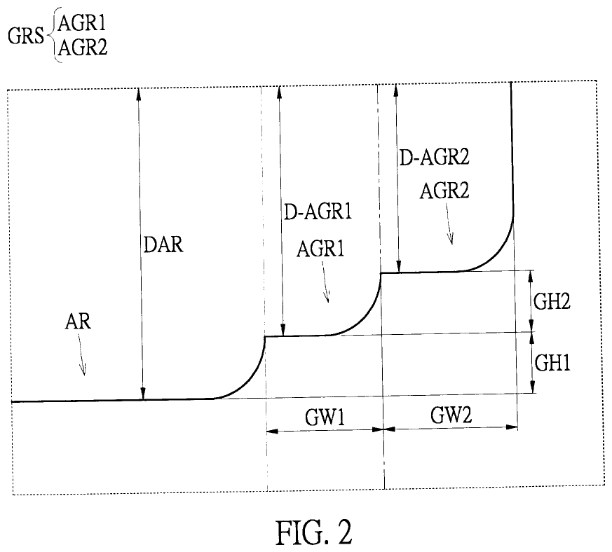

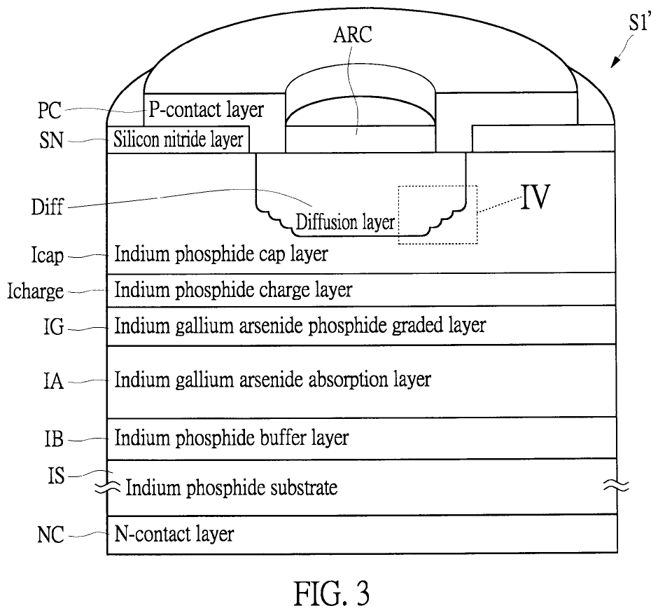

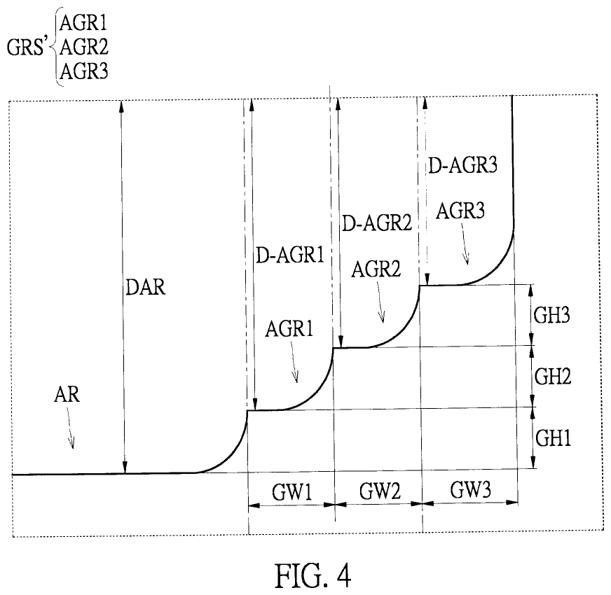

Referring to FIG. 1 to FIG. 4, FIG. 1 is a schematic view of a guard ring structure according to a first embodiment of the present disclosure, FIG. 2 is a schematic enlarged view of region II of FIG. 1, FIG. 3 is another schematic view of the guard ring structure according to the first embodiment of the present disclosure, and FIG. 4 is a schematic enlarged view of region IV of FIG. 3.

Reference is made to FIG. 1, which illustrates a component structure S1 that is multi-layered. From bottom to top, the component structure S1 includes an N-contact layer NC, an indium phosphide substrate IS, an indium phosphide buffer layer IB, an indium gallium arsenide absorption layer IA, an indium gallium arsenide phosphide graded layer IG, an indium phosphide charge layer Icharge, an indium phosphide cap layer Icap, a diffusion layer Diff, a silicon nitride layer SN, a P-contact layer PC, and an active-region coating layer ARC.

In the diffusion layer Diff, phosphorus (P) and zinc are used as diffusion materials. The present embodiment provides a guard ring structure GRS, which is applicable to an active region AR. The guard ring structure GRS includes a first attached guard ring AGR1 and a second attached guard ring AGR2. The drawings of the present embodiment are all illustrated as cross-sectional views. Each actual structure takes up a certain area, and can have a circular, rectangular, or irregular shape. However, the present disclosure is not limited thereto.

The first attached guard ring AGR1 and the second attached guard ring AGR2 are each an attached guard ring (AGR). That is, the first attached guard ring AGR1 is disposed adjacent to a periphery of the active region AR, and the second attached guard ring AGR2 is disposed adjacent to a periphery of the first attached guard ring AGR1. In terms of structure, the first attached guard ring AGR1 and the second attached guard ring AGR2 jointly form a stepped structure due to having the same attached guard ring structure.

Reference is made to FIG. 1 and FIG. 2. In the present embodiment, from an overall circuit structure perspective, a bottom reference point of the active region AR is relative to a top point of the overall component structure, and the active region AR has an active region depth DAR. Relative to the top point of the component structure, the first attached guard ring AGR1 has a first attached guard ring depth D-AGR1, and the second attached guard ring AGR2 has a second attached guard ring depth D-AGR2.

The second attached guard ring depth D-AGR2 is less than the first attached guard ring depth D-AGR1, and the first attached guard ring depth D-AGR1 is less than the active region depth DAR.

Reference is made to FIG. 2, which shows the enlarged region II of FIG. 1. A height difference between the first attached guard ring AGR1 and the active region AR is a first ring height GH1, and a width of the first attached guard ring AGR1 is a first ring width GW1. A height difference between the second attached guard ring AGR2 and the first attached guard ring AGR1 is a second ring height GH2, and a width of the second attached guard ring AGR2 is a second ring width GW2.

The height difference (i.e., the first ring height GH1) between the active region AR and the first attached guard ring AGR1, and the height difference (i.e., the second ring height GH2) between the second attached guard ring AGR2 and the first attached guard ring AGR1 can range between 0.2 μm and 0.4 μm. A relationship between the first ring width GW1 and the second ring width GW2 can be expressed by the following Formula (1): GW2/(GW1+GW2)=25% to 50%.

That is, a ratio of a width value of the second ring width GW2 to a sum of a width value of the first ring width GW1 and the width value of the second ring width GW2 is greater than or equal to 0.25 and less than or equal to 0.5.

In the present embodiment, when a width relationship between the first attached guard ring AGR1 and the second attached guard ring AGR2 is within the 25% to 50% range of the above-mentioned Formula (1), a suppression effect on a fringe field is significant.

Referring to FIG. 3 and FIG. 4, FIG. 4 shows the enlarged region IV of FIG. 3. Similar to the component structure of FIG. 1, a guard ring structure GRS' of a component structure S1′ further includes a third attached guard ring AGR3. The third attached guard ring AGR3 is disposed adjacent to a periphery of the second attached guard ring AGR2. In the present embodiment, when two guard rings are disposed adjacent to one another, no other semiconductor structure is disposed therebetween. The third attached guard ring AGR3 has a third ring width GW3, and a relationship between the third ring width GW3 and the second ring width GW2 is similar to that between the second ring width GW2 and the first ring width GW1 as expressed by the above-mentioned Formula (1). Similarly, a height difference between the third attached guard ring AGR3 and the second attached guard ring AGR2 is a third ring height GH3. The third ring height GH3 can also range, for example, between 0.2 μm and 0.4 μm. Furthermore, the first ring width GW1 is greater than or equal to 4 μm, and the second ring width GW2 and the third ring width GW3 are only required to satisfy the relationship as expressed by the above-mentioned Formula (1). Relative to the top point of the component structure, the third attached guard ring AGR3 has a third attached guard ring depth D-AGR3, and the third attached guard ring depth D-AGR3 is less than the second attached guard ring depth D-AGR2.

From another perspective, the multiple attached guard rings AGR1, AGR2 or the multiple attached guard rings AGR1, AGR2, AGR3 of the present embodiment are multi-step attached guard rings formed through etching of a single-step attached guard ring.

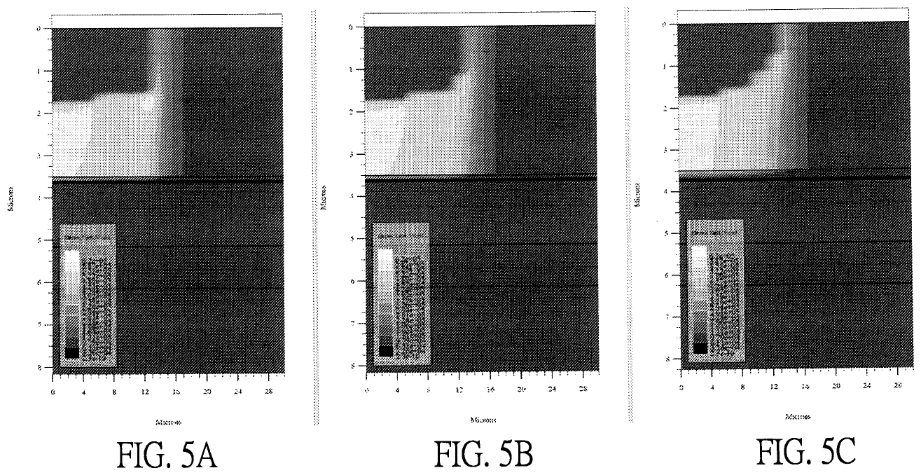

Referring to FIG. 5A, FIG. 5B. and FIG. 5C, FIG. 5A is an electric field distribution diagram of a single attached guard ring, FIG. 5B is an electric field distribution diagram of the guard ring structure of FIG. 1, and FIG. 5C is an electric field distribution diagram of the guard ring structure of FIG. 3. An electric field distribution is shown in grayscale. It can be observed from the electric field distribution of the single attached guard ring in FIG. 5A that the fringe field in a region of the attached guard ring is more outwardly distributed.

FIG. 5B and FIG. 5C are schematic diagrams showing the electric field distribution of the guard ring structures of FIG. 1 and FIG. 3, respectively. Compared with a conventional guard ring (the single-step guard ring of FIG. 5A), the electric field distribution in each of FIG. 5B and FIG. 5C is more concentrated in a middle region (the active region AR), so that a photo-responsivity can be effectively enhanced. In addition, the guard ring structure (the stepped attached guard rings) of the present embodiment is more capable of suppressing edge breakdown. Since an electric field in the middle region (the active region AR) of the present embodiment is more concentrated, detection efficiency and jitter can also be more effectively improved.

The guard ring structure GRS of the present embodiment is a stepped guard ring structure formed by the multiple attached guard rings. Compared with a floating guard ring (FGR), the guard ring structure GRS of the present embodiment takes up a smaller component area (the floating guard ring can be disposed only when being spaced apart by a certain distance), such that more components are capable of being manufactured on a substrate of the same size. Accordingly, overall manufacturing costs can be decreased. Moreover, the component structures S1, S1′ can be the main structure of an avalanche photodiode (APD). Since the component structures S1, S1′ of the present embodiment can effectively improve characteristics of the avalanche photodiode, the avalanche photodiode that has the stepped attached guard rings can become the main choice for a receiving end in application of LIDAR and light quantum. That is, due to excellent properties of said avalanche photodiode, component characteristics can be improved in application and development of LIDAR or light quantum.

### Second Embodiment

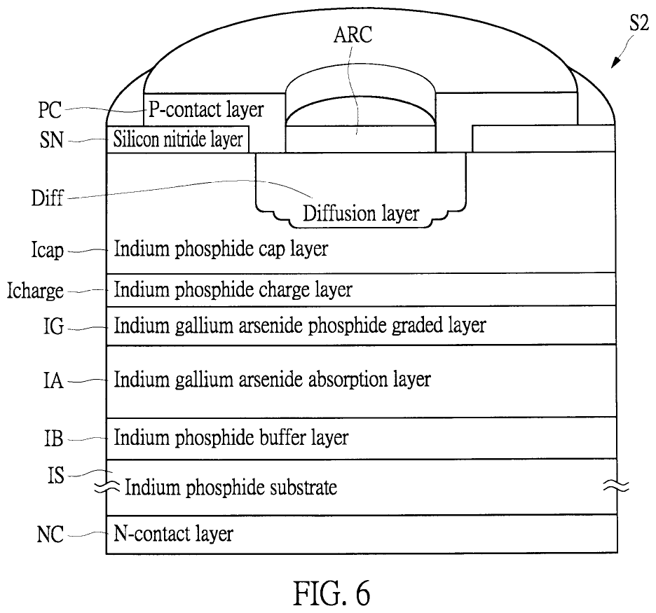

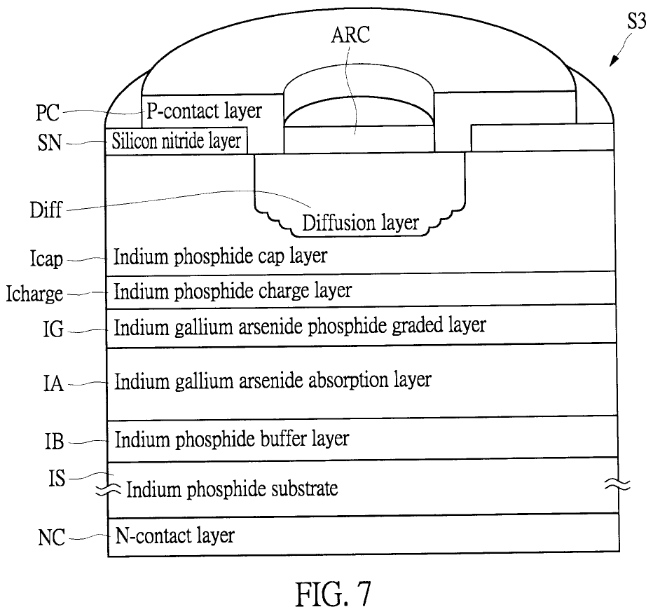

Referring to FIG. 6 and FIG. 7, FIG. 6 is a schematic view of a component structure according to a second embodiment of the present disclosure, and FIG. 7 is another schematic view of the component structure according to the second embodiment of the present disclosure.

The present embodiment provides a component structure S2 and a component structure S3. The component structure S2 includes the active region AR and the guard ring structure GRS. The component structure S3 of FIG. 7 includes the active region AR and the guard ring structure GRS′. Similarly, each of the component structure S2 and the component structure S3 at least includes an N-contact layer NC, an indium phosphide substrate IS, an indium phosphide buffer layer IB, an indium gallium arsenide absorption layer IA, an indium gallium arsenide phosphide graded layer IG, an indium phosphide charge layer Icharge, an indium phosphide cap layer Icap, a diffusion layer Diff, a silicon nitride layer SN, a P-contact layer PC, and an active-region coating layer ARC.

Similar to what is shown in FIG. 2, the guard ring structure GRS of the component structure S2 is disposed at the periphery of the active region AR. The guard ring structure GRS includes the multiple attached guard rings AGR1, AGR2, and the attached guard rings AGR1, AGR2 jointly form a stepped structure. That is, the active region AR is at a lowest point, and the attached guard rings AGR1, AGR2 of the guard ring structure GRS gradually increase in height, such that the stepped structure having multiple steps is formed. Although the two-step attached guard rings AGR1, AGR2 are illustrated in FIG. 6, a quantity of the attached guard rings included in the guard ring structure GRS can be adjusted according to practical requirements. As shown in FIG. 7, the quantity of the attached guard rings is three. In the present embodiment, the quantity of the attached guard rings included in each of the guard ring structures GRS, GRS' is N, and N is a natural number that is greater than or equal to two. Moreover, in the present embodiment, the attached guard rings AGR1, AGR2 of the guard ring structure GRS are attached guard rings having the same structure.

Reference is made to FIG. 7. Similar to what is shown in FIG. 4, the guard ring structure GRS' of the component structure S3 further includes the third attached guard ring AGR3. The third attached guard ring AGR3 is disposed at the periphery of the second attached guard ring AGR2. Similarly, the third attached guard ring AGR3, the first attached guard ring AGR1, and the second attached guard ring AGR2 are all attached guard rings having the same structure. The first attached guard ring AGR1, the second attached guard ring AGR2, and the third attached guard ring AGR3 of the guard ring structure GRS also jointly form a stepped structure that increases in height in a stepwise manner.

The height difference (i.e., the first ring height GH1) between the active region AR and the first attached guard ring AGR1, and the height difference (i.e., the second ring height GH2) between the second attached guard ring AGR2 and the first attached guard ring AGR1 can range between 0.2 μm and 0.4 μm. The relationship between the first ring width GW1 and the second ring width GW2 is as expressed by the above-mentioned Formula (1).

In addition, the height difference between the third attached guard ring AGR3 and the second attached guard ring AGR2 of FIG. 7 can be set within the range between 0.2 μm and 0.4 μm. The relationship between the third ring width GW3 of the third attached guard ring AGR3 and the second ring width GW2 can also be expressed by the above-mentioned Formula (1).

The active region AR can be the main component structure for application of LIDAR, avalanche photodiodes, or light quantum, and the component structures S2, S3 can be the main structure of the avalanche photodiode. Since the component structures S2, S3 of the present embodiment can effectively improve characteristics of the avalanche photodiode, the avalanche photodiode that has the stepped attached guard rings can become the main choice for a receiving end in application of LIDAR and light quantum. That is, due to excellent properties of said avalanche photodiode, component characteristics can be improved in application and development of LIDAR or light quantum.

### Beneficial Effects of the Embodiments

In conclusion, in the guard ring structure and the component structure provided by the present disclosure, the attached guard rings that form two or more steps and have the same structure are used for suppression of the edge breakdown and for concentration of the electric field in the active region, so as to effectively improve detection efficiency and jitter. Furthermore, the guard ring structure of the present disclosure can be used in the component structure of various LIDAR devices and avalanche photodiodes. Instead of using the floating guard ring, the attached guard ring is divided into two, or the single attached guard ring is divided into more than two attached guard rings that are disposed adjacent to one another. In this way, an area utilization rate can be effectively decreased, thereby lowering manufacturing costs and improving component characteristics.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A guard ring structure, which is applicable to an active region, the guard ring structure comprising:
a first attached guard ring disposed at a periphery of the active region; and
a second attached guard ring disposed at a periphery of the first attached guard ring;
wherein the first attached guard ring and the second attached guard ring are each an attached guard ring, and form a stepped structure.

2. The guard ring structure according to claim 1, wherein a height difference between the first attached guard ring and the active region is a first ring height, a height difference between the second attached guard ring and the first attached guard ring is a second ring height, and the first ring height and the second ring height range between 0.2 μm and 0.4 μm.

3. The guard ring structure according to claim 1, wherein the first attached guard ring has a first ring width, and the second attached guard ring has a second ring width; wherein a ratio of a width value of the second ring width to a sum of a width value of the first ring width and the width value of the second ring width is greater than or equal to 0.25 and less than or equal to 0.5.

4. The guard ring structure according to claim 3, further comprising a third attached guard ring disposed at a periphery of the second attached guard ring.

5. The guard ring structure according to claim 4, wherein a height difference between the third attached guard ring and the second attached guard ring is a third ring height, and the third ring height ranges between 0.2 μm and 0.4 μm.

6. The guard ring structure according to claim 5, wherein the third attached guard ring has a third ring width, and a ratio of a width value of the third ring width to a sum of the width value of the second ring width and the width value of the third ring width is greater than or equal to 0.25 and less than or equal to 0.5; wherein the first ring width is greater than or equal to 4 μm.

7. A component structure, comprising:
an active region; and
a guard ring structure disposed at a periphery of the active region, wherein the guard ring structure includes a plurality of attached guard rings, and the attached guard rings jointly form a stepped structure.

8. The component structure according to claim 7, wherein the guard ring structure includes a first attached guard ring and a second attached guard ring, the first attached guard ring is disposed at the periphery of the active region, and the second attached guard ring is disposed at a periphery of the first attached guard ring.

9. The component structure according to claim 8, wherein the guard ring structure further includes a third attached guard ring disposed at a periphery of the second attached guard ring.
